(19) United States
(12) Patent Application Publication
(10) Pub. No.: US 2017/0313046 A1
(43) Pub. Date: Nov. 2, 2017

(54) MANUFACTURING METHOD FOR LAMINATED BODY

(71) Applicant: SUMITOMO CHEMICAL COMPANY, LIMITED, Tokyo (JP)

(72) Inventors: Masami MAKIDERA, Tsukuba-shi (JP); Yasuhiro YAMASHITA, Tsukuba-shi (JP); Mitsunori NODONO, Tsukuba-shi (JP); Satoshi OKAMOTO, Osaka-shi (JP)

(73) Assignee: SUMITOMO CHEMICAL COMPANY, LIMITED, Tokyo (JP)

(21) Appl. No.: 15/517,081

(22) PCT Filed: Oct. 7, 2015
(86) PCT No.: PCT/JP2015/078533

§ 371 Date: Apr. 5, 2017

(30) Foreign Application Priority Data
Oct. 9, 2014 (JP) 2014-208087

(51) Int. Cl. B32B 37/20; B32B 37/12; B32B 7/12; H01L 51/52; C23C 16/50

(52) U.S. Cl. CPC B32B 37/20; H01L 51/5253; C23C 16/50; B32B 7/12; B32B 37/12; B32B 2307/54

(57) ABSTRACT

A manufacturing method for a laminated body having a laminated film and an adhesive layer, the manufacturing method including a step of forming the adhesive layer on one surface of the laminated film, wherein the laminated film is a laminated film on which at least a substrate, and a thin film layer containing at least silicon are laminated; and the step of forming the adhesive layer includes forming the adhesive layer on a surface of a laminated film material in which the thin film layer is laminated, while conveying the laminated film material in which the laminated film is continuous in strip shape in a lengthwise direction, and while applying a tensile force of at least 0.5 N/mm² and less than 50 N/mm² per unit of cross-sectional area, in the lengthwise direction, to the laminated film material.

### TECHNICAL FIELD

The present invention relates to a manufacturing method for a laminated body.

The present application claims priority on the basis of Japanese Patent Application No. 2014-208087, filed in Japan on Oct. 9, 2014, the content of which is incorporated herein by reference.

### BACKGROUND ART

In recent years, organic electroluminescent elements (organic EL elements) have been studied for use as light-emitting elements in display devices or illumination devices. Organic EL elements comprise an anode, an organic light-emitting layer and a cathode, and are formed so that the anode and the cathode sandwich the organic light-emitting layer therebetween. Electrons injected from the cathode and holes injected from the anode bind to form excitons in the organic light-emitting layer located between the two electrodes, and these excitons release energy and thereby emit light.

However, in organic EL elements, when the light-emitting layer or the electrodes come into contact with moisture or oxygen, the light-emitting layer or the electrodes may deteriorate, resulting in light-emission defect portions in the elements. For this reason, organic EL devices provided with organic EL elements employ configurations wherein the periphery of an organic EL element is sealed with a sealing material so as to prevent contact between the organic EL element and moisture or oxygen.

An example of such a sealing material for use in organic EL devices is a laminated body formed by laminating a gas-barrier film having a gas barrier layer (thin film layer) of an inorganic compound formed on the surface of a synthetic resin substrate, and an adhesive layer (see, for example, Patent Literature 1).

### RELATED LITERATURE

### Patent Literature

### [Patent Literature 1]

JP 07-153570 A

### SUMMARY OF INVENTION

### Technical Problem

In general, when wishing to process film-shaped molded bodies in bulk, it is possible to use a manufacturing method that involves continuously processing a raw material (film material) from which the film-shaped molded body is continuously drawn in the form of a strip, then appropriately cutting the molded bodies after processing, thereby obtaining the processed molded bodies in bulk.

When attempting to manufacture the above-mentioned laminated body using such a manufacturing method, there is a risk of damaging the thin film layer having the gas barrier property or of causing appearance defects due to waving of the surface of the adhesive layer, so improvements are sought.

The present invention has been made in consideration of these circumstances, and has the purpose of providing a manufacturing method for a laminated body, capable of suppressing the occurrence of damage to a thin film layer having a gas barrier property and the occurrence of appearance defects.

### Solution to Problem

In order to solve the above-mentioned problems, one embodiment of the present invention provides a manufacturing method for a laminated body having a laminated film and an adhesive layer formed on one surface of the laminated film, wherein the laminated film has a substrate and a thin film layer containing at least silicon and formed between the substrate and the adhesive layer, and the manufacturing method comprises a step of forming the adhesive layer on one surface of a laminated film material, while conveying the laminated film material in which the laminated film is continuous in a strip shape in a lengthwise direction, and while applying a tensile force of at least 0.5 N/mm² and less than 50 N/mm² per unit of cross-sectional area, in the lengthwise direction, to the laminated film material.

In one embodiment of the present invention, the manufacturing method may be such that the step of forming the adhesive layer, using an adhesive layer material in which the adhesive layer is continuous in a strip shape, involves bonding the adhesive layer material onto the laminated film material, while conveying the adhesive layer material in the lengthwise direction, and while applying a tensile force of at least 0.01 N/mm² and less than 5 N/mm² per unit of cross-sectional area, in the lengthwise direction, to the adhesive layer material.

In one embodiment of the present invention, the manufacturing method may further have a step of continuously forming the thin film layer on at least one surface of a substrate material while continuously conveying the substrate material in which the substrate is continuous in a strip shape.

In one embodiment of the present invention, the manufacturing method may be such that the step of forming the thin film layer involves using plasma CVD using a discharge plasma of a film-forming gas, which is a material for forming the thin film layer, generated in a space between a first film formation roller over which the substrate material is wound, and a second film formation roller over which the substrate material is wound and which faces the first film formation roller, by applying an AC voltage between the first film formation roller and the second film formation roller.

In one embodiment of the present invention, the manufacturing method may be such that, by forming an AC electric field between the first film formation roller and the second film formation roller, and forming an endless tunnel-shaped magnetic field extending in the space across which the first film formation roller and the second film formation roller face each other, the discharge plasma includes a first discharge plasma that is formed along the tunnel-shaped magnetic field, and a second discharge plasma that is formed in the periphery of the tunnel-shaped magnetic field; and the step of forming the thin film layer is performed by conveying the substrate material so as to coincide with the first discharge plasma and the second discharge plasma.

In one embodiment of the present invention, the thin film layer contains at least silicon, oxygen and carbon, and the step of forming the thin film layer includes controlling the mixing ratio between an organic silicon compound and oxygen contained in the film-forming gas so that, in the formed thin film layer, a silicon distribution curve, an oxygen distribution curve and a carbon distribution curve, respectively indicating the relationship between the distance from the surface of the thin film layer, and the ratio of the number of silicon atoms (the atomic ratio of silicon), the ratio of the number of oxygen atoms (the atomic ratio of oxygen), and the ratio of the number of carbon atoms (the atomic ratio of carbon), with respect to the total number of silicon atoms, oxygen atoms and carbon atoms contained in the thin film layer at a point located at that distance, satisfy the following conditions (i) to (iii):

(i) the atomic ratio of silicon, the atomic ratio of oxygen and the atomic ratio of carbon satisfy the conditions represented by the following expression (1) in a region that is at least 90% of the entire film thickness of the thin film layer:

(Atomic ratio of oxygen)>(atomic ratio of silicon)>(atomic ratio of carbon) (1);

(ii) the carbon distribution curve has at least one extreme value; and

(iii) the absolute value of the difference between the maximum value and the minimum value of the atomic ratio of carbon in the carbon distribution curve is at least 0.05.

In one embodiment of the present invention, the manufacturing method may be such that the absolute value of the difference between the maximum value and the minimum value of the atomic ratio of silicon in the silicon distribution curve of the thin film layer is less than 5 at %.

In one embodiment of the present invention, the manufacturing method may be such that the thin film layer comprises SiOₓC_{y}, where 0<x<2 and 0<y<2.

In other words, the present invention includes the following embodiments.

[1] A manufacturing method for a laminated body having a laminated film and an adhesive layer,

the manufacturing method comprising a step of forming the adhesive layer on one surface of the laminated film, wherein

the laminated film is a laminated film on which at least a substrate, and a thin film layer containing at least silicon are laminated, and

the step of forming the adhesive layer includes forming the adhesive layer on a surface of a laminated film material in which the thin film layer is laminated, while conveying the laminated film material in which the laminated film is continuous in strip shape in a lengthwise direction, and while applying a tensile force of at least 0.5 N/mm² and less than 50 N/mm² per unit of cross-sectional area, in the lengthwise direction, to the laminated film material.

[2] The manufacturing method for a laminated body according to [1], wherein the step of forming the adhesive layer further includes bonding an adhesive layer material, onto the laminated film material, while conveying the adhesive layer material in which the adhesive layer is continuous in strip shape in the lengthwise direction, and while applying a tensile force of at least 0.01 N/mm² and less than 5 N/mm² per unit of cross-sectional area, in the lengthwise direction, to the adhesive layer material.
[3] The manufacturing method for a laminated body according to [1] or [2], further comprising a step of forming the thin film layer on at least one surface of the substrate;

wherein the step of forming the thin film layer includes continuously forming the thin film layer on at least one surface of a substrate material, while continuously conveying the substrate material in which the substrate is continuous in strip shape.

[4] The manufacturing method for a laminated body according to [3], wherein the step of forming the thin film includes:

applying an AC voltage between a first film formation roller over which the substrate material is wound, and a second film formation roller over which the substrate material is wound and which is provided so as to face the first film formation roller, thereby generating a discharge plasma of a film-forming gas, which is a material for forming the thin film layer, in a space between the first film formation roller and the second film formation roller; and

forming the thin film layer on the surface of the substrate material by plasma CVD using the generated discharge plasma.

[5] The manufacturing method for a laminated body according to [4], wherein

the AC voltage is applied and a magnetic field is formed so that, by forming an AC electric field between the first film formation roller and the second film formation roller, and forming an endless tunnel-shaped magnetic field extending in the space across which the first film formation roller and the second film formation roller face each other, the discharge plasma includes a first discharge plasma that is formed along the tunnel-shaped magnetic field, and a second discharge plasma that is formed in a periphery of the tunnel-shaped magnetic field; and

the step of forming the thin film layer includes conveying the substrate material so as to coincide with the first discharge plasma and the second discharge plasma.

[6] The manufacturing method for a laminated body according to [4] or [5], wherein:

the thin film layer contains at least silicon, oxygen and carbon; and

the step of forming the thin film layer includes controlling a mixing ratio between an organic silicon compound and oxygen contained in the film-forming gas so that, in the formed thin film layer, a silicon distribution curve, an oxygen distribution curve and a carbon distribution curve, respectively indicating a relationship between the distance from a surface of the thin film layer in a film thickness direction of the thin film layer, and the atomic ratio of silicon, which is the ratio of the number of silicon atoms, the atomic ratio of oxygen, which is the ratio of the number of oxygen atoms, and the atomic ratio of carbon, which is the ratio of the number of carbon atoms, with respect to the total number of silicon atoms, oxygen atoms and carbon atoms contained in the thin film layer at a point located at the distance, satisfy the following conditions (i) to (iii):

(i) the atomic ratio of silicon, the atomic ratio of oxygen and the atomic ratio of carbon satisfy the conditions represented by the following expression (1) in a region that is at least 90% of the entire film thickness of the thin film layer:

(Atomic ratio of oxygen)>(atomic ratio of silicon)>(atomic ratio of carbon) (1);

(ii) the carbon distribution curve has at least one extreme value; and

(iii) the absolute value of the difference between the maximum value and the minimum value of the atomic ratio of carbon in the carbon distribution curve is at least 0.05 at %.

[7] The manufacturing method for a laminated body according to [6], wherein the absolute value of the difference between the maximum value and the minimum value of the atomic ratio of silicon in the silicon distribution curve of the thin film layer is less than 5 at %.
[8] The manufacturing method for a laminated body according to any one of [1] to [7], wherein the thin film layer comprises SiOₓC_{y}, where 0<x<2 and 0<y<2.

### Advantageous Effects of Invention

According to the present invention, it is possible to provide a manufacturing method for a laminated body, capable of suppressing the occurrence of damage to a thin film layer having a gas-barrier property and the occurrence of appearance defects.

### BRIEF DESCRIPTION OF DRAWINGS

FIG. 1 is a schematic diagram illustrating an example of a laminated body manufactured by the manufacturing method for a laminated body according to an embodiment of the present invention.

FIG. 2 is a schematic diagram illustrating a thin film layer in a laminated body according to the manufacturing method for a laminated body according to an embodiment of the present invention.

FIG. 3 is an explanatory diagram illustrating a manufacturing method for a laminated body according to a first embodiment of the present invention.

FIG. 4 is an explanatory diagram illustrating a manufacturing method for a laminated body according to the first embodiment of the present invention.

FIG. 5 is an explanatory diagram illustrating a manufacturing method for a laminated body according to a second embodiment of the present invention.

FIG. 6 is an explanatory diagram illustrating a modification example of the manufacturing method for a laminated body according to an embodiment of the present invention.

FIG. 7 is a schematic diagram illustrating an organic EL device using a laminated body manufactured by the manufacturing method for a laminated body according to an embodiment of the present invention.

FIG. 8 is a graph showing the silicon distribution curve, the oxygen distribution curve, the nitrogen distribution curve and the carbon distribution curve in Laminated Film 1 obtained in Manufacturing Example 1.

### DESCRIPTION OF EMBODIMENTS

### First Embodiment

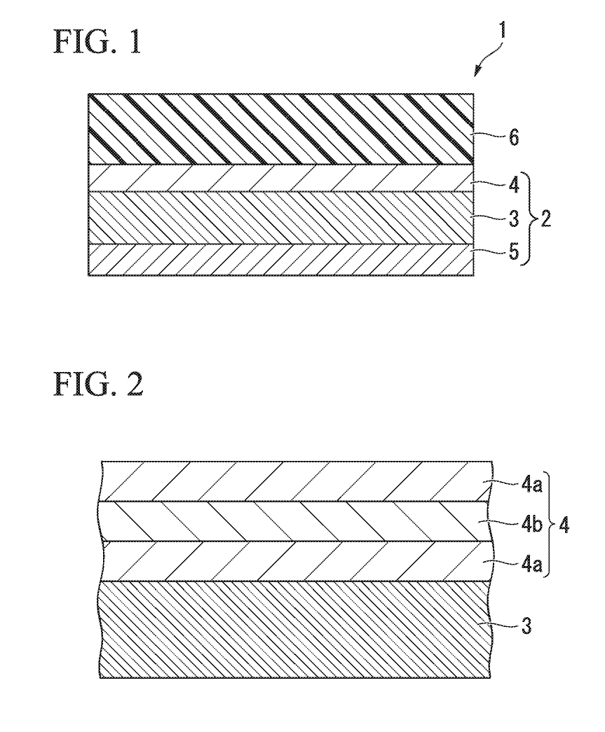

Hereinafter, a manufacturing method for a laminated body according to a first embodiment of the present invention will be explained with reference to FIG. 1-4. In all of the following drawings, the dimensions and proportions of the constituent elements have been appropriately modified in order to make the drawings easier to see.

### [Laminated Body]

FIG. 1 is a schematic diagram illustrating an example of a laminated body manufactured by the manufacturing method for a laminated body according to the present embodiment. The laminated body 1 has a laminated film 2, and an adhesive layer 6 formed on one surface of the laminated film 2.

### (Laminated Film)

In the laminated body 1 according to the present embodiment, the laminated film 2 has a substrate 3, a thin film layer 4 formed so as to be sandwiched between the substrate 3 and the adhesive layer 6, and a curl-suppressing layer 5 provided on the surface of the substrate 3 opposite to the surface on which the thin film layer 4 is provided.

In other words, in one aspect, the laminated body 1 according to the present embodiment has a laminated film 2 and an adhesive layer 6; the laminated film 2 has a substrate 3, a thin film layer 4 and a curl-suppressing layer 5; the thin film layer 4 is provided between the substrate 3 and the adhesive layer 6, and the curl-suppressing layer 5 is provided on the surface of the substrate 3 opposite to the surface on which the thin film layer 4 is provided.

### (Substrate)

Examples of the material forming the substrate 3 include polyester resins such as polyethylene terephthalate (PET) and polyethylene naphthalate (PEN); polyolefin resins such as polyethylene (PE), polypropylene (PP) and cyclic polyolefins; polyamide resins; polycarbonate resins; polystyrene resins; polyvinyl alcohol resins; saponified ethylene-polyvinyl acetate copolymers; polyacrylonitrile resins; acetal resins; polyimide resins; and polyether sulfides (PES); two or more of which may be used in combination as needed. The material should preferably be chosen from the group consisting of polyester resins and polyolefin resins in accordance with the required properties such as transparency, heat resistance and linear expansion properties. More preferably, the material should be chosen from the group consisting of PET, PEN and cyclic polyolefins. Additionally, examples of composite materials containing resins include silicone resins such as polydimethylsiloxane and polysilsesquioxane; glass composite substrates; and glass epoxy substrates. Among these materials, polyester resins, polyolefin resins, glass composite substrates and glass epoxy substrates are preferable in view of their high heat resistance and low linear expansion coefficient. Additionally, these materials may be used as one type alone or as a combination of two or more types.

In the laminated body 1 of the present embodiment, PEN is used as the material forming the substrate 3.

The thickness of the substrate 3 may be set as appropriate in consideration of the stability or the like when manufacturing the laminated film, but a thickness of 5 μm to 500 μm is preferable due to the ease of conveyance of the substrate 3 in a vacuum. Furthermore, in the laminated film used in the manufacturing method of the present embodiment, an electrical discharge is passed through the substrate 3 during the formation of the thin film layer 4, as will be described below, so the thickness of the substrate 3 should preferably be 50 μm to 200 μm, and more preferably 50 μm to 100 μm.

The “thickness of the substrate” may be determined as the average value of the distance from surface to surface in the thickness direction of the substrate at nine arbitrary locations.

The substrate 3 may be subjected to a surface activation treatment in order to clean the surface thereof, in view of the adhesion with the thin film layer 4 that is formed. Examples of such surface activation treatments include corona treatments, plasma treatments and flame treatments.

### (Thin Film Layer)

The thin film layer 4 is provided on the surface of the substrate 3 (in other words, in the laminated body in product form, between the substrate and the adhesive layer), and ensures the gas barrier property. The thin film layer 4 comprises at least one layer, but may comprise a plurality of layers (e.g., 2 to 4 layers), each layer containing at least silicon, oxygen and hydrogen.

FIG. 2 is a schematic diagram illustrating the thin film layer 4. The thin film layer 4 illustrated in the diagram includes first layers 4a containing large quantities of SiO₂ formed by a complete oxidation reaction of the film-forming gas to be described below, and a second layer 4b containing large quantities of SiOₓC_{y} generated by an incomplete oxidation reaction, the first layers 4a and the second layer 4b being alternately laminated to form a three-layer structure. Additionally, at least one layer among the layers constituting the thin film layer 4 may further contain nitrogen, aluminum or titanium.

However, the diagram is merely intended to schematically indicate that there is a distribution in the film composition. There is actually no definite boundary between the first layers 4a and the second layer 4b, and the composition varies continuously. In this diagram, the thin film layer 4 is illustrated as having a three-layer structure, but it is possible to further laminate multiple layers. When the thin film layer 4 is constituted from more than three layers, first layers 4a should be formed on both ends in the lamination direction, and all second layers 4b should be sandwiched between adjacent first layers 4a. In other words, in one aspect, the thin film layer 4 has a structure having, laminated on the surface of a substrate 3, in the following order, a first layer 4a containing large quantities of SiO₂, a second layer 4b containing large quantities of SiOₓC_{y} generated by an incomplete oxidation reaction, and a first layer 4a containing large quantities of SiO₂. In another aspect, the thin film layer 4 is formed by alternately laminating multiple first layers 4a containing large quantities of SiO₂ and second layers 4b containing large quantities of SiOₓC_{y} generated by an incomplete oxidation reaction, such that first layers 4a are provided on both ends in the lamination direction.

### (Curl-Suppressing Layer)

The curl-suppressing layer 5 is provided in order to suppress the curling (warping) of the laminated film 2 overall. The material forming the curl-suppressing layer 5 may be the same material as that used in the above-mentioned thin film layer 4. Additionally, the thickness (hereinafter referred to sometimes as the layer thickness) of the curl-suppressing layer 5 may be set to the same thickness as the above-mentioned thin film layer 4. The thin film layer 4 and the curl-suppressing layer 5 are preferably formed from the same material, have the same layer structure, and have the same thickness. The thickness of the curl-suppressing layer 5 can be determined by means of a method similar to that for the thickness of the thin film layer 4 described below.

Additionally, the curl-suppressing layer 5 need not be formed. In other words, in a different aspect, the laminated body 1 according to the present embodiment has a laminated film 2 and an adhesive layer 6; the laminated film 2 has a substrate 3 and a thin film layer 4; and the thin film layer 4 is provided between the substrate 3 and the adhesive layer 6.

### (Adhesive Layer)

The adhesive layer 6 has the function of adhering the laminated body 1 to another element. As the material forming the adhesive layer 6, any generally known material may be used. For example, a thermosetting resin composition or a photosetting resin composition may be used.

Examples of thermosetting resin compositions include phenolic resins, epoxy resins, melamine resins, urea resins, unsaturated polyester resins, alkyd resins, polyurethane resins and thermosetting polyimides, and the compositions may include solvents, viscosity adjusters or the like as needed. Examples of photosetting resin compositions include acrylate resins and epoxy resins, and the compositions may include solvents, viscosity adjusters or the like as needed.

The adhesive layer 6 may be constituted from a resin composition with residual polymerizable functional groups, such that strong adhesion can be achieved by further polymerizing the resin composition constituting the adhesive layer 6 after adhering the laminated body 1 to another element.

Additionally, the adhesive layer 6 may be formed by using a thermosetting resin composition or a photosetting resin composition as the material, then subsequently supplying energy so as to polymerize and set the resin, or it may be what is known as a pressure-sensitive adhesive (PSA), which is adhered to an object by applying pressure.

As a pressure-sensitive adhesive, it is possible to use an adhesive which is a “substance that has tackiness at room temperature and adheres to an adherend with light pressure” (JIS K6800), or a capsule-type adhesive which is “an adhesive containing a specific component in a protective film (microcapsule), such that the stability can be maintained until the film is broken by an appropriate means (pressure, heat, etc.)” (JIS K6800).

The thickness (hereinafter referred to sometimes as the “film thickness”) of the adhesive layer 6 may be 100 μm or less. If the thickness of the adhesive layer 6 becomes less than 10 μm, then the impact resistance can be expected to decrease and wrinkles will tend to occur, so the thickness should preferably be at least 10 μm. In other words, the thickness of the adhesive layer 6 should preferably be at least 10 μm and at most 100 μm.

The adhesive layer 6 may be composed of a single layer as illustrated in FIG. 1, or may have a laminated structure that is made capable of adhesion on both surfaces by providing adhesive layers on both surfaces of a film serving as a substrate, in the manner of so-called double-sided tape.

The water content of the laminated body 1 should preferably be 0.1 mass % or less with respect to the overall mass of the laminated body 1, in order to suppress the influence on the object sealed by the laminated body 1. The water content of the laminated body 1 may, for example, be lowered by reduced-pressure drying, heat-drying or reduced-pressure heat-drying of the laminated body 1.

The water content of the laminated body 1 can be determined by preparing and precisely weighing a sample piece of approximately 0.1 g from the laminated body 1, heating the sample piece for 3 minutes at 150° C. in a Karl Fischer moisture meter, and measuring the generated moisture content.

The laminated body 1 manufactured using the manufacturing method of the present embodiment has the structure indicated above.

### [Manufacturing Method of Laminated Body]

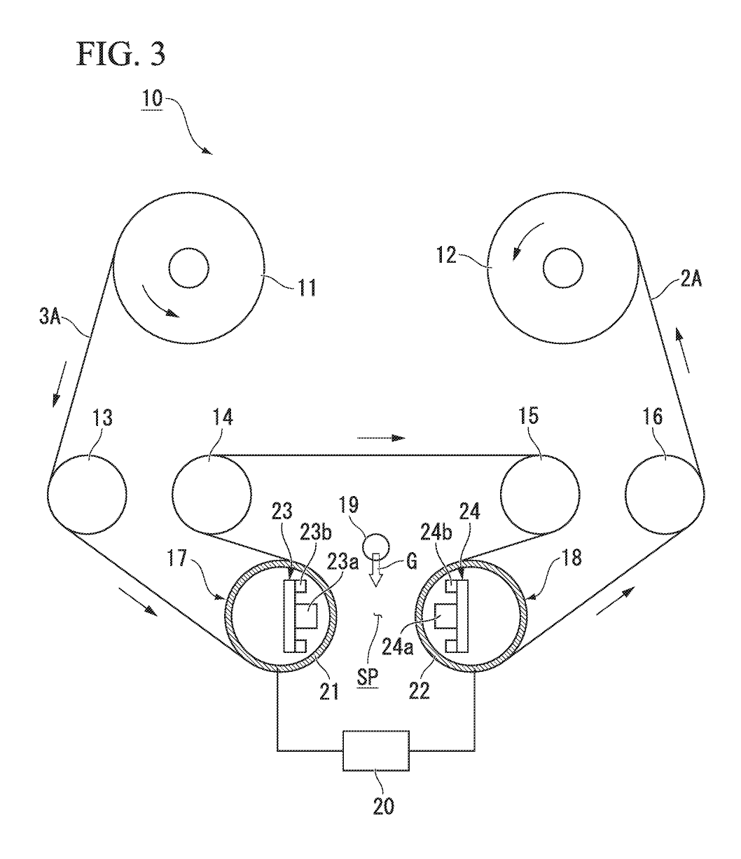

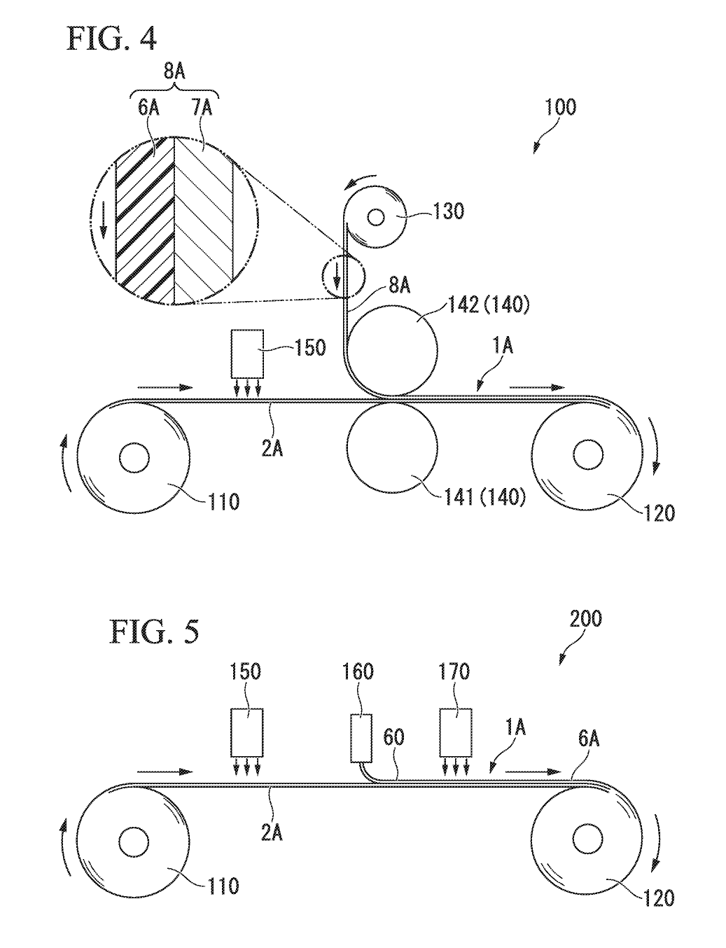

FIGS. 3 and 4 are explanatory diagrams illustrating the manufacturing method for a laminated body according to the present embodiment. The manufacturing method for a laminated body according to the present embodiment comprises a step of forming a thin film layer on a substrate, and a step of forming an adhesive layer on the formed laminated film. In the following description, it will be assumed that the curl-suppressing layer 5 shown in FIG. 1 will not be provided.

### (Step of Forming Thin Film Layer)

FIG. 3 is an explanatory diagram illustrating the step of forming the thin film layer, showing a schematic diagram of a film formation device 10 that carries out the step of forming a thin film layer.

The film formation device 10 illustrated in the drawing is provided with an unwinding roller 11, a winding roller 12, conveyance rollers 13 to 16, film formation rollers 17 and 18, a gas supply pipe 19, a plasma-generating power source 20, electrodes 21 and 22, a magnetic field generation device 23 installed inside the film formation roller 17, and a magnetic field generation device 24 installed inside the film formation roller 18. Among the elements constituting the film formation device 10, at least the film formation rollers 17 and 18, the gas supply pipe 19 and the magnetic field generation devices 23 and 24 are provided inside a vacuum chamber, not illustrated in the drawing, when the laminated film is being manufactured. This vacuum chamber is connected to a vacuum pump, which is not illustrated. The pressure inside the vacuum chamber is adjusted by the action of the vacuum pump.

By using this device, it is possible to generate a discharge plasma of the film-forming gas supplied from the gas supply pipe 19 in the space between the film formation roller 17 and the film formation roller 18, by controlling the plasma-generating power source 20, and the generated discharge plasma can be used to carry out plasma CVD film formation.

In the unwinding roller 11, a substrate material 3A, before film formation, is installed in a wound state, and the substrate is supplied by unwinding the substrate material 3A in the lengthwise direction. Additionally, a winding roller 12, provided at the end of the substrate material 3A, pulls and winds the substrate material 3A after film formation, and accommodates it in the form of a roll.

The substrate material 3A is in the form of a strip, which is cut at predetermined lengths in a direction intersecting the lengthwise direction so as to form the above-mentioned substrate 3 in FIG. 1. The materials forming the substrate material 3A may be materials similar to the above-mentioned materials forming the substrate 3. In the manufacturing method for a laminated body according to the present embodiment, PEN is used as the material forming the substrate material 3A.

The film formation roller 17 and the film formation roller 18 are arranged so as to lie parallel to and facing each other. Both rollers are formed from conductive materials, and each rotates so as to convey the substrate material 3A. Additionally, the film formation roller 17 and the film formation roller 18 are insulated from each other, while being connected to a common plasma-generating power source 20. When power is supplied from the plasma-generating power source 20, an electric field is generated in the space SP between the film formation roller 17 and the film formation roller 18.

Furthermore, the film formation roller 17 and the film formation roller 18 house magnetic field generation devices 23 and 24 in the interiors thereof. The magnetic field generation devices 23 and 24 are elements for generating a magnetic field in the space SP, and are housed so as not to rotate together with the film formation roller 17 and the film formation roller 18.

The magnetic field generation devices 23 and 24 have central magnets 23a and 24a extending in the same direction as the direction of extension of the film formation roller 17 and the film formation roller 18, and annular external magnets 23b and 24b arranged so as to extend in the same direction as the direction of extension of the film formation roller 17 and the film formation roller 18 while surrounding the central magnets 23a and 24a. In the magnetic field generation device 23, the magnetic force lines (magnetic field) connecting the central magnet 23a and the external magnet 23b form an endless tunnel. Likewise, in the magnetic field generation device 24, the magnetic force lines connecting the central magnet 24a and the external magnet 24b form an endless tunnel.

A magnetron discharge which occurs when these magnetic force lines cross the electric field formed between the film formation roller 17 and the film formation roller 18 creates a discharge plasma of the film-forming gas. In other words, as will be described in detail below, the space SP is used as a film formation space for carrying out plasma CVD film formation, where a thin film layer formed from the film-forming gas is formed on the surface of the substrate material 3A that is not in contact with the film formation rollers 17 and 18 (i.e. the film formation surface).

Near the space SP, a gas supply pipe 19 is provided for supplying a film-forming gas such as a raw material gas for plasma CVD to the space SP. The gas supply pipe 19 is in the form of a pipe that extends in the same direction as the direction of extension of the film formation roller 17 and the film formation roller 18, and supplies the film-forming gas to the space SP through apertures provided in multiple locations. FIG. 3 shows arrows indicating how the film-forming gas is supplied from the gas supply pipe 19 to the space SP.

The raw material gas may be appropriately chosen in accordance with the material of the barrier film to be formed. The raw material gas may, for example, be an organic silicon compound containing silicon. Examples of such organic silicon compounds include hexamethyldisiloxane, 1,1,3,3-tetramethyldisiloxane, vinyltrimethylsilane, methyltrimethylsilane hexamethyldisilane, methylsilane, dimethylsilane, trimethylsilane, diethylsilane, propylsilane, phenylsilane, vinyltriethoxysilane, vinyltrimethoxysilane, tetramethoxysilane, tetraethoxysilane, phenyltrimethoxysilane, methyltriethoxysilane, octamethylcyclotetrasiloxane, dimethyldisilazane, trimethyldisilazane, tetramethyldisilazane, pentamethyldisilazane and hexamethyldisilazane. Among these organic silicon compounds, hexamethyldisiloxane and 1,1,3,3-tetramethyldisiloxane are preferable in view of the ease of handling of the compounds and the gas barrier properties of the barrier film. Additionally, these organic silicon compounds may be used as a single type alone or as a combination of two or more types. Furthermore, as the raw material gas, it is possible to include monosilane in addition to the above-mentioned organic silicon compound, for use as a silicon source in the barrier film to be formed.

As a film-forming gas, it is possible to use a reactive gas in addition to the raw material gas. As such a reactive gas, it is possible to appropriately choose and use a gas that reacts with the raw material gas to form inorganic compounds such as oxides and nitrides. A reactive gas for forming oxides may, for example, be oxygen, ozone or the like. Additionally, a reactive gas for forming nitrides may, for example, be nitrogen, ammonia or the like. These reactive gases may be used as a single type alone or as a combination of two or more types, and for example, when forming oxynitrides, it is possible to combine a reactive gas for forming oxides with a reactive gas for forming nitrides.

As a film-forming gas, it is possible to use a carrier gas, as needed, in order to feed the raw material gas into the vacuum chamber. Furthermore, as a film-forming gas, it is possible to use a discharge gas, as needed, in order to generate a discharge plasma. As such carrier gases and discharge gases, it is possible to use known gases, as appropriate. For example, noble gases such as helium, argon, neon and xenon, or hydrogen may be used.

The pressure (vacuum level) inside the vacuum chamber may be appropriately adjusted in accordance with the type of raw material gas or the like, but it is preferable for the pressure inside the space SP to be 0.1 Pa to 50 Pa. When a low-pressure plasma CVD process is used for plasma CVD for the purpose of suppressing the vapor phase reaction, the pressure will usually be set to 0.1 Pa to 10 Pa. Additionally, the power to the electrode drums of the plasma generation device may be adjusted as appropriate in accordance with the type of raw material gas or the pressure inside the vacuum chamber, but it should preferably be 0.1 kW to 10 kW.

The conveyance speed (line speed) of the substrate material 3A may be appropriately adjusted in accordance with the type of raw material gas or the pressure inside the vacuum chamber, but it should preferably be 0.1 m/min to 100 m/min, more preferably 0.5 m/min to 20 m/min. When the line speed is less than the lower limit, wrinkles caused by heat tend to form in the substrate material 3A, while on the other hand, when the line speed exceeds the upper limit, the formed barrier film tends to become thin. In other words, if the line speed is equal to or greater than the lower limit, then the formation of wrinkles caused by heat in the substrate material 3A may be suppressed, and if the line speed is equal to or less than the upper limit, the formed barrier film will have adequate thickness.

In the film-forming device 10 as indicated above, a film is formed on the substrate material 3A in the following manner.

First, before film formation, a pretreatment may be performed in order to adequately reduce outgassing from the substrate material 3A. The outgassing rate from a substrate material 3A can be determined by loading the substrate material 3A in the manufacturing device, and observing the pressure when the inside of the device (the inside of the chamber) is depressurized. For example, if the pressure in the chamber of the manufacturing device is no more than 1×10⁻³ Pa, then the outgassing rate from the substrate material 3A can be judged to be adequately low.

Examples of methods for reducing the outgassing rate from a substrate material 3A include drying methods such as vacuum drying, heat drying, drying by a combination thereof, and natural drying. In all of the drying methods, it is preferable to repeatedly rewind (wind and unwind) the roll during drying so as to expose the entire substrate material 3A to the drying environment, in order to promote the drying of the substrate material 3A that has been wound on the inside of a roll.

Vacuum drying is performed by placing the substrate material 3A inside a pressure-resistance vacuum container, and evacuating the inside of the vacuum container using a pressure reduction device such as a vacuum pump, so as to form a vacuum. The pressure inside the vacuum container during vacuum drying should preferably be at least 1×10⁻⁶ Pa and at most 1000 Pa, more preferably at least 1×10⁻⁵ Pa and at most 100 Pa, and even more preferably at least 1×10⁻⁴ and at most 10 Pa. The evacuation of the inside of the vacuum container may be performed continuously by continuously operating the pressure reduction device, or may be performed intermittently by operating the pressure reduction device intermittently while monitoring the internal pressure so as not to exceed a certain value. The drying time should preferably be at least 8 hours, more preferably at least one week, and even more preferably at least one month.

Heat-drying is performed by exposing the substrate material 3A to an environment having a temperature of at least 50° C. The heating temperature should preferably be at least 50° C. and at most 200° C., and more preferably at least 70° C. and at most 150° C. If the temperature exceeds 200° C., there is a risk of deformation of the substrate material 3A. Additionally, there is a risk of defects occurring as a result of oligomer components being eluted from the substrate material 3A and being deposited on the surface. The drying time may be appropriately chosen in accordance with the heating temperature or the heating means that is used.

The heating means is not particularly limited, as long as it is capable of heating the substrate material 3A to at least 50° C. and at most 200° C. at atmospheric pressure. Among devices that are generally known, infrared heating devices, microwave heating devices and heating drums are preferably used.

In this case, an “infrared heating device” is a device that heats objects by emitting infrared rays from an infrared ray generating means.

A “microwave heating device” is a device that heats objects by emitting microwaves from a microwave generating means.

A “heating drum” is a device that heats a drum surface and brings an object into contact with the drum surface so as to heat the object by heat conduction from the contacting part.

Natural drying is performed by placing the substrate material 3A in a low-humidity atmosphere, and maintaining the low-humidity atmosphere by ventilating with a dry gas (dry air or dry nitrogen). During natural drying, it is preferable to also place a desiccant such as a silica gel in the low-humidity environment in which the substrate material 3A is placed. The drying time should preferably be at least 8 hours, more preferably at least one week, and even more preferably at least one month.

These drying processes may be separately performed before the substrate material 3A is loaded in the manufacturing device, or may be performed inside the manufacturing device after the substrate material 3A has been loaded into the manufacturing device.

An example of a method for drying the substrate material 3A after it has been loaded in the manufacturing device is a method wherein the pressure inside the chamber is reduced while unwinding the substrate material 3A from the unwinding roller and conveying the substrate material 3A. Additionally, a roller across which the substrate material 3A passes may be provided with a heater so as to heat the roller, so that the substrate material 3A is heated by using the roller as the above-mentioned heating drum.

An example of another method for reducing outgassing from the substrate material 3A is to form an inorganic film on the surface of the substrate material 3A beforehand. Examples of film formation methods for the inorganic film include physical film formation methods such as vacuum vapor deposition (thermal vapor deposition), electron beam (EB) vapor deposition, sputtering and ion plating. Additionally, the inorganic film may also be formed by a chemical deposition method such as thermal CVD, plasma CVD or atmospheric pressure CVD. The effects of outgassing may be further reduced by subjecting a substrate material 3A having an inorganic film formed on the surface to a drying treatment according to one of the above-mentioned drying methods.

In other words, in one aspect of the manufacturing method of the present invention, in order to sufficiently reduce outgassing from the substrate material 3A before forming the thin film layer, vacuum drying, heat drying, drying by a combination of vacuum drying and heat drying, and natural drying may be performed, or an inorganic film may be formed on the surface of the substrate material 3A.

Next, a reduced pressure environment is formed inside the vacuum chamber, not illustrated in the drawings, and power is supplied to the film formation roller 17 and the film formation roller 18 so as to generate an electric field in the space SP.

At this time, the above-mentioned endless tunnel-shaped magnetic field is formed by the magnetic field generation devices 23 and 24. Therefore, by introducing a film-forming gas, the electrons that are released into the space SP and the magnetic field cause a donut-shaped discharge plasma of the film-forming gas to be formed along the tunnel. This discharge plasma can be generated at a low pressure of about a few Pa, so the temperature inside the vacuum chamber can be made close to room temperature.

On the other hand, since the electrons that are trapped at a high density in the magnetic field formed by the magnetic field generation devices 23 and 24 are at a high temperature, a discharge plasma is generated by collisions between the electrons and the film-forming gas. In other words, a high-density discharge plasma is formed in the space SP by electrons being trapped inside the space SP by the magnetic field and the electric field formed in the space SP. More specifically, in the spaces overlapping with the endless tunnel-shaped magnetic field, a high-density (high-intensity) discharge plasma is formed, and in the spaces no overlapping with the endless tunnel-shaped magnetic field, a low-density (low-intensity) discharge is formed. The intensities of these discharge plasmas vary continuously.

When a discharge plasma is generated, many radicals and ions are generated, the plasma reaction progresses, and reactions occur between the raw material gas and the reactive gas contained in the film-forming gas. For example, organic silicon compounds comprising a raw material gas can react with oxygen comprising a reactive gas, causing the organic silicon compounds to undergo an oxidation reaction.

In the space in which the high-intensity discharge plasma is formed, a lot of energy is imparted to the oxidation reaction, so the reaction more easily progresses, and it is possible to induce mainly complete oxidation reactions of the organic silicon compounds. On the other hand, in the space in which the low-intensity discharge plasma is formed, little energy is imparted to the oxidation reaction, so the reaction cannot easily progress, and it is possible to induce mainly incomplete oxidation reactions of the organic silicon compounds.

In the present specification, a “complete oxidation reaction of organic silicon compounds” refers to a reaction wherein the reaction between the organic silicon compounds and the oxygen progresses until the organic silicon compounds are oxidatively decomposed into silicon dioxide (SiO₂), water and carbon dioxide. An “incomplete oxidation reaction of organic silicon compounds” refers to a reaction wherein a complete oxidation reaction of the organic silicon compounds does not occur, and SiOₓC_{y} (0<x<2, 0<y<2), containing carbon in the structure, is generated instead of SiO₂.

As mentioned above, the discharge plasma is formed in the shape of a donut at the surfaces of the film-forming roller 17 and the film-forming roller 18, so the substrate material 3A conveyed over the surfaces of the film formation roller 17 and the film formation roller 18 passes alternately through a space where a high-intensity discharge plasma is formed, and a space where a low-intensity discharge plasma is formed. Therefore, SiO₂ generated by a complete oxidation reaction and SiOₓC_{y} generated by an incomplete oxidation reaction are alternately formed on the surface of the substrate material 3A passing over the surfaces of the film-forming roller 17 and the film-forming roller 18.

In addition thereto, high-temperature secondary electrons are prevented from flowing to the substrate material 3A by the action of the magnetic field. As a result, a high electric power can be applied while keeping the temperature of the substrate material 3A low, so high-speed film formation is achieved. Since the deposition of the film occurs mainly on only the film formation surface of the substrate material 3A and the film-forming rollers are covered by the substrate material 3A and are not susceptible to contamination, stable film formation can be achieved over a long period of time.

In the thin film layer 4 formed in this way, the thin film layer 4 containing silicon, oxygen and carbon satisfies all of the following conditions (i) to (iii) in terms of a silicon distribution curve, an oxygen distribution curve and a carbon distribution curve, respectively indicating the relationship between the distance from the surface of the layer in the film thickness direction of the layer and the ratio of the amount of silicon atoms (hereinafter referred to sometimes as the atomic ratio of silicon), the ratio of the amount of oxygen atoms (hereinafter referred to sometimes as the atomic ratio of oxygen) and the ratio of the amount of carbon atoms (hereinafter referred to sometimes as the atomic ratio of carbon) with respect to the total amount of silicon atoms, oxygen atoms and carbon atoms.

(i) First, in the thin film layer 4, the atomic ratio of silicon, the atomic ratio of oxygen and the atomic ratio of carbon satisfy the conditions represented by the following expression (1) in a region that is at least 90% and at most 100% (more preferably at least 95% and at most 100%, and particularly preferably 100%) of the film thickness of the layer.

(Atomic ratio of oxygen)>(atomic ratio of silicon)>(atomic ratio of carbon) (1);

When the atomic ratio of silicon, the atomic ratio of oxygen and the atomic ratio of carbon in the thin film layer 4 satisfy the condition in (i), the resulting gas-barrier laminated film has sufficient gas barrier properties.

(ii) Furthermore, in the thin film layer 4, the carbon distribution curve has at least one extreme value.

In the thin film layer 4, the carbon distribution curve more preferably has at least two extreme values, and particularly preferably has a least three extreme values. When there is no extreme value in the carbon distribution curve, the gas barrier properties are insufficient when the film of the resulting gas-barrier laminated film is bent. Additionally, when there are at least three extreme values in this way, it is preferable for the absolute values of the differences in the distances from the surface of the thin film layer 4, in the film thickness direction of the thin film layer 4, between one extreme value in the carbon distribution curve and another extreme value adjacent to that extreme value, to be no more than 200 nm, and more preferably no more than 100 nm.

In the present embodiment, an “extreme value” refers to a maximum value or a minimum value of the atomic ratio of an element in the thin film layer 4 as a function of the distance from the surface of the thin film layer 4 in the film thickness direction of the thin film layer 4. Additionally, in the present specification, “maximum value” refers to a point at which the value of the atomic ratio for an element in the thin film layer 4 changes from an increasing state to a decreasing state when varying the distance from the surface of the thin film layer 4, such that the value of the atomic ratio (atomic composition percentage) of the element is reduced by at least 3 at % compared to the value of the atomic ratio of the element at said point when the distance from the surface of the thin film layer 4 is further changed from said point by 20 nm in the film thickness direction of the thin film layer 4. Furthermore, in the present embodiment, a “minimum value” refers to a point at which the value of the atomic ratio for an element in the thin film layer 4 changes from a decreasing state to an increasing state when varying the distance from the surface of the thin film layer 4, such that the value of the atomic ratio of the element is increased by at least 3 at % compared to the value of the atomic ratio of the element at said point when the distance from the surface of the thin film layer 4 is further changed from said point by 20 nm in the film thickness direction of the thin film layer 4.

(iii) Furthermore, in the thin film layer 4, the absolute value of the difference between the maximum value and the minimum value of the atomic ratio of carbon in the carbon distribution curve is at least 5 at %.

In the thin film layer 4, the absolute value of the difference between the maximum value and the minimum value of the atomic ratio of carbon is preferably at least 6 at %, and particularly preferably at least 7 at %. When the absolute value is less than 5 at %, the gas barrier properties are insufficient when the film of the resulting gas-barrier laminated film is bent. In other words, if the absolute value is at least 5 at %, the gas barrier properties are sufficient when the film of the resulting gas-barrier laminated film is bent.

In the present embodiment, the oxygen distribution curve of the thin film layer 4 preferably has at least one extreme value, more preferably at least two extreme values, and particularly preferably at least three extreme values. When the oxygen distribution curve has no extreme values, the gas barrier properties tend to be decreased when the film of the resulting gas-barrier laminated film is bent. Additionally, when there are at least three extreme values in this way, it is preferable for the absolute values of the differences in the distances from the surface of the thin film layer 4, in the film thickness direction of the thin film layer 4, between one extreme value in the oxygen distribution curve and another extreme value adjacent to that extreme value, to be no more than 200 nm, and more preferably no more than 100 nm.

Additionally, in the present embodiment, the absolute value of the difference between the maximum value and the minimum value of the atomic ratio of oxygen in the oxygen distribution curve of the thin film layer 4 is preferably at least 5 at %, more preferably at least 6 at %, and particularly preferably at least 7 at %. When the absolute value is less than the lower limit, the gas barrier properties tend to decrease when the film of the resulting gas-barrier laminated film is bent. In other words, if the absolute value is equal to or greater than the lower limit, it is possible to suppress reductions in the gas barrier properties when the film of the resulting gas-barrier laminated film is bent.

In the present embodiment, the absolute value of the difference between the maximum value and the minimum value of the atomic ratio of silicon in the silicon distribution curve of the thin film layer 4 is preferably less than 5 at %, more preferably less than 4 at %, and particularly preferably less than 3 at %. When the absolute value exceeds the upper limit, the gas barrier properties of the resulting gas-barrier laminated film tend to decrease. In other words, if the absolute value is equal to or less than the upper limit, it is possible to suppress reductions in the gas barrier properties of the resulting gas-barrier laminated film.

Additionally, in the present embodiment, in the thin film layer 4, an oxygen-carbon distribution curve indicating the relationship between the distance from the surface of the layer in the film thickness direction of the thin film layer 4 and the ratio of the total amount of oxygen atoms and carbon atoms (atomic ratios of carbon and oxygen) with respect to the total amount of silicon atoms, oxygen atoms and carbon atoms is preferably such that the absolute value of the difference between the maximum value and the minimum value of the sum of the atomic ratios of oxygen and carbon in the oxygen-carbon distribution curve is less than 5 at %, more preferably less than 4 at %, and particularly preferably less than 3 at %. When the absolute value exceeds the upper limit, the gas barrier properties of the resulting gas-barrier laminated film tend to decrease. In other words, if the absolute value is equal to or less than the upper limit, it is possible to suppress reductions in the gas barrier properties of the resulting gas-barrier laminated film.

In this case, the silicon distribution curve, the oxygen distribution curve, the carbon distribution curve and the oxygen-carbon distribution curve can be prepared by so-called XPS (X-ray photoelectron spectroscopy) depth profile measurement wherein the interior of a sample is exposed while sequentially performing surface composition analysis, by taking XPS measurements while simultaneously sputtering with ions of a noble gas such as argon. A distribution curve obtained by such XPS depth profile measurements can, for example, be prepared by plotting the atomic ratios (in units of at %) of the respective elements on the vertical axis and the etching time (sputtering time) on the horizontal axis. In an element distribution curve having the etching time on the horizontal axis in this manner, the etching time is roughly correlated with the distance from the surface of the thin film layer 4 in the film thickness direction, so it is possible to use, as the “distance from the surface of the thin film layer 4 in the film thickness direction of the thin film layer 4”, the distance from the surface of the thin film layer 4 calculated from the relationship between the etching rate and the etching time used when making the XPS depth profile measurements. Additionally, as the sputtering method used when performing the XPS depth profile measurements, it is preferable to use a noble gas sputtering method with argon (Ar⁺) as the etching ion species, and to set the etching rate to 0.05 nm/sec (SiO₂ thermal oxidation film conversion).

Additionally, in the present embodiment, in order to form a thin film layer 4 that is homogeneous and that has excellent gas barrier properties across the entire film surface, it is preferable for the thin film layer 4 to be substantially uniform in the film surface direction (i.e. the direction parallel to the surface of the thin film layer 4). In the present specification, “the thin film layer 4 is substantially uniform in the film surface direction” refers to the case wherein, when an oxygen distribution curve, a carbon distribution curve and an oxygen-carbon distribution curve are prepared by XPS depth profile measurements at two arbitrary measurement sites on the film surface of the thin film layer 4, the number of extreme values in the carbon distribution curve obtained at the two measurement sites is the same, and the absolute values of the differences between the maximum values and the minimum values of the atomic ratio of carbon in the respective carbon distribution curves are the same or differ by 5 at % or less.

Furthermore, in the present embodiment, it is preferable for the carbon distribution curve to be substantially continuous.

In the present specification, “the carbon distribution curve is substantially continuous” refers to the case wherein the atomic ratio of carbon in the carbon distribution curve does not include any discontinuously changing portions, and specifically, means that the relationship between the distance (x, in units of nm) from the surface of the layer in the film thickness direction of the thin film layer 4 calculated from the etching rate and the etching time, and the atomic ratio of carbon (C, in units of at %), satisfies the following expression (F1):

|dC/dx|≦0.01 (F1)

The expression “dC” represents the atomic ratio of carbon from the surface of the layer in the film thickness direction of the thin film layer 4 calculated from the etching rate and the etching time, and “dx” represents the distance from the surface of the layer in the film thickness direction of the thin film layer 4 calculated from the etching rate and the etching time.

The gas-barrier laminated film manufactured by the method of the present embodiment comprises at least one thin film layer 4 satisfying all of the above-mentioned conditions (i) to (iii), but it may also comprise two or more layers satisfying the conditions. Furthermore, when there are two or more such thin film layers 4, the materials of the plurality of thin film layers 4 may be the same or different. Additionally, when there are two or more such thin film layers 4, the thin film layers 4 may be formed on one surface of the substrate, or may be formed on both surfaces of the substrate. Additionally, such a plurality of thin film layers 4 may include a thin film layer 4 not necessarily having a gas barrier property.

Additionally, when the atomic ratio of silicon, the atomic ratio of oxygen and the atomic ratio of carbon in the silicon distribution curve, the oxygen distribution curve and the carbon distribution curve satisfy the conditions represented by expression (1) over a region spanning at least 90% of the film thickness of the layer, the atomic ratio of the silicon atom content with respect to the total amount of silicon atoms, oxygen atoms and carbon atoms in the thin film layer 4 should preferably be at least 25 at % and at most 45 at %, and more preferably at least 30 at % and at most 40 at %. Additionally, the atomic ratio of the oxygen atom content with respect to the total amount of silicon atoms, oxygen atoms and carbon atoms in the thin film layer 4 should preferably be at least 33 at % and at most 67 at %, and more preferably at least 45 at % and at most 67 at %. Furthermore, the atomic ratio of the carbon atom content with respect to the total amount of silicon atoms, oxygen atoms and carbon atoms in the thin film layer 4 should preferably be at least 3 at % and at most 33 at %, and more preferably at least 3 at % and at most 25 at %.

Furthermore, when the atomic ratio of silicon, the atomic ratio of oxygen and the atomic ratio of carbon in the silicon distribution curve, the oxygen distribution curve and the carbon distribution curve satisfy the conditions represented by expression (2) over a region spanning at least 90% of the film thickness of the layer, the atomic ratio of the silicon atom content with respect to the total amount of silicon atoms, oxygen atoms and carbon atoms in the thin film layer 4 should preferably be at least 25 at % and at most 45 at %, and more preferably at least 30 at % and at most 40 at %. Additionally, the atomic ratio of the oxygen atom content with respect to the total amount of silicon atoms, oxygen atoms and carbon atoms in the thin film layer 4 should preferably be at least 1 at % and at most 33 at %, and more preferably at least 10 at % and at most 27 at %. Furthermore, the atomic ratio of the carbon atom content with respect to the total amount of silicon atoms, oxygen atoms and carbon atoms in the thin film layer 4 should preferably be at least 33 at % and at most 66 at %, and more preferably at least 40 at % and at most 57 at %.

Additionally, the thickness (also called the film thickness) of the thin film layer 4 should preferably be within the range of at least 5 nm and at most 3,000 nm, more preferably within the range of at least 10 nm and at most 2,000 nm, and particularly preferably within the range of at least 100 nm and at most 1,000 nm. When the thickness of the thin film layer 4 is less than the lower limit, the gas barrier properties such as the oxygen gas barrier property and the water vapor barrier property tends to become worse, and on the other hand, when the upper limit is exceeded, the gas barrier properties tend to decrease as a result of being bent. In other words, when the thickness of the thin film layer 4 is equal to or greater than the lower limit, the gas barrier properties such as the oxygen gas barrier property and the water vapor barrier property are good, and when it is equal to or less than the upper limit, the gas barrier properties do not tend to be reduced as a result of being bent.

Additionally, when the gas-barrier laminated film in the present embodiment is provided with a plurality of thin film layers 4, the sum of the thicknesses (film thicknesses) of the thin film layers 4 should normally be within the range from at least 10 nm to at most 10,000 nm, preferably within the range from at least 10 nm and at most 5,000 nm, more preferably within the range from at least 100 nm to at most 3,000 nm, and particularly preferably within the range from at least 200 nm to at most 2,000 nm. When the sum of the thicknesses of the thin film layers 4 is less than the lower limit, the gas barrier properties such as the oxygen gas barrier property and the water vapor barrier property tend to decrease as a result of being bent. In other words, when the sum of the thicknesses of the thin film layers 4 is equal to or greater than the lower limit, the gas barrier properties such as the oxygen gas barrier property and the water vapor barrier property are good, and when it is equal to or less than the upper limit, the gas barrier properties do not tend to be reduced as a result of being bent.

In order to form such a thin film layer 4, the ratio between the raw material gas and the reactive gas contained in the film-forming gas should preferably be set so that the ratio of the reactive gas is not excessively greater than the ratio of the amount of reactive gas that is theoretically necessary to completely react the raw material gas with the reactive gas. If the reactive gas ratio is set to be excessively large, then a thin film layer 4 satisfying all of the above-mentioned conditions (i) to (iii) cannot be obtained.

Herebelow, the preferred ratio between the raw material gas and the reactive gas in the film-forming gas and the like will be explained in detail by providing an example of a case in which a silicon-oxygen thin film layer is manufactured by using a film-forming gas comprising hexamethyldisiloxane (HMDSO: (CH₃)₆Si₂O) as the raw material gas and oxygen (O₂) as the reactive gas.

When manufacturing a silicon-oxygen thin film layer by using plasma CVD to react a film-forming gas comprising HMDSO as the raw material gas and oxygen as the reactive gas, the film-forming gas undergoes the reaction described by the following reaction formula (1), producing silicon dioxide.

[Formula 1]

(CH₃)₆Si₂O+12O₂→6CO₂+9H₂O+SiO₂ (1)

In such a reaction, the amount of oxygen necessary to completely oxidize 1 mole of HMDSO is 12 moles. Therefore, if at least 12 moles of oxygen are contained in the film-forming gas with respect to 1 mole of HMDSO, a uniform silicon dioxide film will be formed, so it becomes impossible to form a thin film layer 4 that satisfies all of the above-mentioned conditions (i) to (iii). For this reason, when forming the thin film layer 4 of the present embodiment, it is necessary to make the amount of oxygen with respect to 1 mole of HMDSO less than 12 moles, which is the stoichiometric ratio, so that the reaction of the above-mentioned formula (1) does not completely progress.

With the reaction in the vacuum chamber 10 of the film formation device 10, the HMDSO which is the raw material and the oxygen which is the reactive gas are supplied from gas supply portions to the film formation region for film formation, so even if the molar amount (flow rate) of the oxygen reactive gas were 12 times the molar amount (flow rate) of the HMDSO raw material, in actuality, the reaction would not be able to progress completely, and it is believed that the reaction would be completed only upon supplying a large excess of oxygen content relative to the stoichiometric ratio (for example, in order to obtain silicon oxide by complete oxidation by CVD, the molar amount (flow rate) of oxygen is sometimes set to be approximately 20 times or more of the molar amount (flow rate) of the HMDSO raw material). For this reason, it is preferable for the molar amount (flow rate) of oxygen with respect to the molar amount (flow rate) of the HMDSO raw material to be an amount that is 12 times or less (more preferably 10 times or less) of the stoichiometric ratio.

By containing HMDSO and oxygen in this ratio, carbon atoms and hydrogen atoms in the HMDSO that were not completely oxidized are taken into the thin film layer 4, making it possible to form a thin film layer 4 satisfying all of the above-mentioned conditions (i) to (iii), and enabling excellent barrier properties and bending resistance properties to be achieved in the resulting gas-barrier laminated film.

If the molar amount (flow rate) of oxygen is too low relative to the molar amount (flow rate) of HMDSO in the film-forming gas, non-oxidized carbon atoms and hydrogen atoms are excessively taken into the thin film layer 4, and in this case, the transparency of the barrier film is reduced. Such a gas-barrier film cannot be used as a flexible substrate for use in a device requiring transparency, such as an organic EL device or an organic thin-film solar cell. In view thereof, the lower limit of the molar amount (flow rate) of oxygen relative to the molar amount (flow rate) of HMDSO in the film-forming gas should preferably be greater than 0.1 times, and more preferably greater than 0.5 times, the molar amount (flow rate) of HMDSO.

In other words, the molar amount (flow rate) of oxygen relative to the molar amount (flow rate) of HMDSO in the film-forming gas should preferably be at least 0.1 times and at most 12 times, and more preferably at least 0.5 times and at most 10 times the molar amount (flow rate) of HMDSO.

Whether or not the organic silicon compounds are completely oxidized can be controlled not only by controlling the mixing ratio between the raw material gas and the reactive gas in the film-forming gas, but also by controlling the voltage applied to the film formation roller 17 and the film formation roller 18.

Plasma CVD using a discharge plasma in this way is capable of continuously forming a thin film layer 4 on the surface of a substrate material 3A wound around the film formation roller 17 and the film formation roller 18.

If the curl-suppressing layer 5 is to be formed, it is formed, after the formation of the thin film layer 4, on the surface of the substrate material 3A opposite from the surface on which the thin film layer 4 is formed. By forming the curl-suppressing layer 5 under the same conditions as those used when forming the thin film layer 4, it can be formed with the same composition, the same structure and the same layer thickness (thickness) as the thin film layer 4. Of course, by making the conditions for forming the curl-suppressing layer 5 different from the conditions for forming the thin film layer 4, the composition, layer structure and film thickness of the curl-suppressing layer 5 may be made different from those of the thin film layer 4.

In other words, in one aspect, the manufacturing method for a laminated body according to the present invention comprises a step of forming an adhesive layer, a step of forming a thin film layer, and a further step of forming a curl-suppressing layer if desired. The step of forming the curl-suppressing layer may be performed under the same conditions as those for the step of forming the thin film layer, or under different conditions.

As a result, it is possible to manufacture a laminated film material 2A, which is a continuous strip of the laminated film. The laminated film material 2A is cut at predetermined lengths in a direction intersecting the lengthwise direction so as to form laminated films 2.

### (Step of Forming Adhesive Layer)

FIG. 4 is an explanatory diagram illustrating the step of forming the adhesive layer, showing a schematic diagram of a manufacturing device 100 that carries out the step of forming an adhesive layer.

The manufacturing device 100 illustrated in the drawing comprises a first unwinding roller 110, a winding roller 120, a second unwinding roller 130, a bonding roller 140 and a surface treatment device 150.

A laminated film material 2A is loaded, in a wound state, in the first unwinding roller 110, with the thin film layer facing outward, and the laminated film material 2A is supplied by being unwound in the lengthwise direction.

The winding roller 120 is provided at the end of the laminated film material 2A, pulls and winds the laminated film material 2A after formation of the adhesive layer (the laminated body material 1A to be described below), and accommodates it in the form of a roll.

An adhesive film 8A in the form of a strip is loaded, in a wound state, onto the second unwinding roller 130, and the adhesive film 8A is supplied by being unwound in the lengthwise direction. The adhesive film 8A has an adhesive layer 6A formed in a strip on one surface of a separator film 7A that is in the form of a strip, and is wound onto the second unwinding roller 130 with the adhesive layer 6A facing outward.

The adhesive layer 6A corresponds to the “adhesive layer material” in the present invention. As the material forming the adhesive layer 6A, it is possible to use a material similar to the material forming the above-mentioned adhesive layer 6.

A separator film 7A is peelably bonded to one surface of the adhesive layer 6A. By peeling the separator film 7A from the adhesive film 8A, the adhesive layer 6A is exposed and can be adhered.

The bonding roller 140 has a pair of rollers, i.e. a roller 141 and a roller 142. At the bonding roller 140, the laminated film material 2A and the adhesive film 8A are made to enter from the same direction into the gap between the pair or rollers, and the laminated film material 2A and the adhesive film 8A are pinched and pressed between the pair of rollers so as to bond them together to form a laminated body material 1A. Specifically, at the bonding roller 140, the thin film layer of the laminated film material 2A and the adhesive layer 6A of the adhesive film 8A are bonded in a state facing each other so as to form the laminated body material 1A. The laminated body material 1A is cut at predetermined lengths in a direction intersecting the lengthwise direction to form laminated bodies 1 which are the object to be obtained by the manufacturing method for a laminated body according to the present embodiment.

In the manufacturing method for a laminated body according to the present embodiment, the laminated film material 2A and the adhesive film 8A are bonded together while applying a tensile force of at least 0.5 N/mm² and less than 50 N/mm² per unit of cross-sectional area, in the lengthwise direction, to the laminated film material 2A, so as to form the adhesive layer on one surface of the laminated film material 2A. In the manufacturing device 100, the tensile force on the laminated film material 2A between the first unwinding roller 110 and the bonding roller 140 is within the above-mentioned range.

In the present specification, the cross-sectional area in “unit of cross-sectional area” refers to the cross-section when cut along a plane perpendicular to the lengthwise direction.

In other words, one aspect of the manufacturing method for a laminated body according to the present embodiment includes forming an adhesive layer on one surface of the laminated film material 2A by bonding together the laminated film material 2A and the adhesive film 8A while applying at least 0.5 N/mm² and less than 50 N/mm² of tensile force per unit of cross-sectional area, in the lengthwise direction, to the laminated film material 2A.

By applying the above-mentioned tensile force to the laminated film material 2A, even if the laminated film material 2A that was wound into a roll in the first unwinding roller 110 is curved, it can be satisfactorily bonded to the adhesive film 8A, and appearance defects will not tend to occur.

Additionally, if the tensile force applied to the laminated film material 2A is at least 0.5 N/mm², wrinkles will not tend to be formed on the laminated body material 1A, and appearance defects will not tend to occur. Additionally, if the tensile force applied to the laminated film material 2A is less than 50 N/mm², the thin film layer will not tend to be damaged even when an impact is applied to the manufactured laminated body 1, and the gas barrier properties can be more easily maintained.

Additionally, in the manufacturing method for a laminated body according to the present embodiment, it is preferable to form an adhesive layer on one surface of the laminated film material 2A by bonding together the laminated film material 2A and the adhesive film 8A while applying a tensile force of at least 0.01 N/mm² and less than 5 N/mm² per unit of cross-sectional area, in the lengthwise direction, to the adhesive film 8A. The tensile force to be applied is more preferably at least 0.1 N/mm² and less than 0.5 N/mm² per unit of cross-sectional area. In the manufacturing device 100, the tensile force of the adhesive film 8A between the second unwinding roller 130 and the bonding roller 140 is within the above-mentioned range.

In other words, one aspect of the manufacturing method for a laminated body according to the present embodiment includes forming an adhesive layer on one surface of the laminated film material 2A by bonding together the laminated film material 2A and the adhesive film 8A while applying at least 0.01 N/mm² and less than 5 N/mm² of tensile force per unit of cross-sectional area, in the lengthwise direction, to the adhesive film 8A.

If the tensile force applied to the adhesive film 8A is at least 0.01 N/mm², wrinkles will not tend to be formed on the laminated body material 1A, and appearance defects will not tend to occur. Additionally, if the tensile force applied to the adhesive film 8A is less than 5 N/mm², there is little risk that the adhesive film 8A will be stretched and deformed, and the laminated body 1 can easily be manufactured as designed.

The tensile force applied to the laminated film material 2A can be controlled by adjusting the unwinding speed (rotation speed) of the first unwinding roller 110 and the rotation speed of the bonding roller 140. Additionally, the tensile force applied to the adhesive film 8A can be controlled by adjusting the unwinding speed (rotation speed) of the second unwinding roller 130 and the rotation speed of the bonding roller 140. By adjusting the rotation speed of the bonding roller 140, both the tensile force applied to the laminated film material 2A and the tensile force applied to the adhesive film 8A are affected, so that when the tensile forces are to be controlled separately, it is better to adjust the rotation speed of the first unwinding roller 110 or the second unwinding roller 130.

The bonding roller 140 may have a configuration wherein the pair of rollers 141 and 142 are heated. With a bonding roller 140 of this configuration, the laminated film material 2A and the adhesive film 8A can be bonded while softening them by heating the laminated film material 2A and the adhesive film 8A, making it possible to increase the area of contact between the surfaces (bonding surfaces) facing each other, so an effect of improving the adhesion can be expected. Additionally, if the material forming the adhesive layer 6A is a thermosetting resin, then the setting can be accelerated.

The heating temperature should be a temperature exceeding the glass transition temperature (Tg) of at least one of either the resin constituting the laminated film material 2A or the resin constituting the adhesive film 8A. With such a temperature, it is possible to thermally deform the laminated film material 2A or the adhesive film 8A, and the above-mentioned effect of improving the adhesion can be expected.

The pressure during bonding should preferably be controlled, for example, to be at least 0.1 MPa and at most 0.5 MPa.

The surface treatment device 150 is provided on the conveyance path of the laminated film material 2A between the first unwinding roller 110 and the bonding roller 140. The surface treatment device 150 is provided at a position where the surface of the thin film layer, which is the surface of the laminated film material 2A facing the adhesive film 8A, can be treated. The surface treatment device 150 subjects the surface of the thin film layer to a plasma treatment, a UV ozone treatment, a corona treatment or the like. As a result, at the surface of the thin film layer, impurities are removed and the amount of polar groups such as hydroxyl groups is increased, thereby allowing the adhesion between the laminated film material 2A and the adhesive film 8A to be improved (allowing the peeling strength to be improved).

In addition thereto, the manufacturing device 100 may have publicly known features such as a winding roller for winding a protective film on the adhesive film 8A, or a conveyance roller used when conveying the films.

From a laminated body material 1A manufactured as indicated above, for example, by cutting it at predetermined lengths in a direction intersecting with the lengthwise direction while unwinding it from the winding roller 120, laminated bodies 1 having a separator film bonded to an adhesive layer 6 can be obtained.

In other words, as one aspect of the manufacturing method for a laminated body according to the present invention, it may further include cutting the laminated body material 1A, formed by the aforementioned manufacturing steps, in a direction intersecting with the lengthwise direction.

Furthermore, the aforementioned method may include peeling the separator film.

The manufacturing method for a laminated body according to the present embodiment is configured as described above.

According to the manufacturing method for a laminated body configured as above, it is possible to provide a manufacturing method for a laminated body that is able to suppress damage to the thin film layer having a gas barrier property and to suppress the occurrence of appearance defects.

### Second Embodiment

FIG. 5 is an explanatory diagram for the manufacturing method for a laminated body according to a second embodiment of the present invention. The manufacturing method for a laminated body according to the present embodiment is partially the same as the manufacturing method for the laminated body according to the first embodiment, and differs in the step for forming the adhesive layer. Therefore, in the present embodiment, the elements that are the same as those in the first embodiment will be assigned the same reference numbers, and their detailed descriptions will be omitted.

### (Step of Forming Adhesive Layer)

FIG. 5 is an explanatory diagram representing the step of forming the adhesive layer in the present embodiment, and is a schematic diagram showing a manufacturing device 200 for implementing a step of forming an adhesive layer.

The manufacturing device 200 illustrated in the drawing comprises a first unwinding roller 110, a winding roller 120, a surface treatment device 150, a coating device 160 and a curing device 170.

The coating device 160 is provided on the conveyance path of the laminated film material 2A between the surface treatment device 150 and the winding roller 120. The coating device 160 coats a precursor composition for the adhesive layer, in liquid form, onto the surface of the thin film layer, which is the surface of the laminated film material 2A facing the adhesive film 8A.

The coating device has a tank, not illustrated, that stores the precursor composition, a coating portion, facing the laminated film material 2A, that discharges the precursor composition, and a liquid delivery pump, not illustrated, provided on a pipe connecting the tank with the coating portion. In FIG. 5, only the coating portion is illustrated, indicated by reference number 160.

As the coating portion, it is possible to use a generally known configuration that is capable of coating the liquid precursor composition, such as, for example, a dispenser, a die coater, a bar coater, a slit coater, a spray coating device or a printer.

The precursor composition may be a composition (photosetting composition) containing a curable resin, a photopolymerization initiator, and a solvent or viscosity adjuster or the like as needed, or a composition (thermosetting composition) containing a thermally decomposable polymerization initiator instead of a photopolymerization initiator. In the present embodiment, a photosetting composition is used.

By adjusting the amount of the precursor composition coated by the coating device 160 and the conveyance speed of the laminated film material 2A by the first unwinding roller 110 and the winding roller 120, it is possible to control the thickness (film thickness) of the coating film 60 of the precursor composition formed on the surface of the laminated film material 2A.

The curing device 170 has the function of accelerating the curing of the coating film 60. Since a photosetting composition is used as the precursor composition in the present embodiment, a light source capable of emitting light such as, for example, ultraviolet rays, is used as the curing device 170. In the curing device 170, the coating film 60 is irradiated with ultraviolet rays, and in the coating film 60 irradiated with ultraviolet rays, a polymerization reaction is promoted by a photopolymerization reaction, thereby curing the coating film and forming an adhesive layer 6A. When the precursor composition coated by the coating device 160 is a thermosetting composition, a heat source such as an infrared irradiation device or a heater is used as the curing device 170.

In the manufacturing method for a laminated body according to the present embodiment, the coating film 60 is formed on the surface of the laminated film material 2A while applying a tensile force of at least 0.5 N/mm² and less than 50 N/mm² per unit of cross-sectional area, in the lengthwise direction, to the laminated film material 2A, so as to form the adhesive layer on one surface of the laminated film material 2A. In the manufacturing device 100, the tensile force on the laminated film material 2A between the first unwinding roller 110 and the winding roller 120 is within the above-mentioned range.

In other words, one aspect of the manufacturing method for a laminated body according to the present invention includes forming an adhesive layer on one surface of the laminated film material 2A by forming the coating film 60 on the surface of the laminated film material 2A while applying a tensile force of at least 0.5 N/mm² and less than 50 N/mm² per unit of cross-sectional area, in the lengthwise direction, to the laminated film material 2A.

If the tensile force applied to the laminated film material 2A is at least 0.5 N/mm², then the film thickness of the formed coating film 60 will not tend to become uneven, wrinkles will not tend to form on the laminated body material 1A, and appearance defects will not tend to occur. Additionally, if the tensile force applied to the laminated film material 2A is less than 50 N/mm², the thin film layer will not tend to be damaged even when an impact is applied to the manufactured laminated body 1, and the gas barrier properties can be easily maintained.

From a laminated body material 1A manufactured as indicated above, for example, by cutting it at predetermined lengths in a direction intersecting with the lengthwise direction while unwinding it from the winding roller 120, laminated bodies 1 can be obtained.

In other words, as one aspect of the manufacturing method for a laminated body according to the present invention, it may further include cutting the laminated body material 1A, formed by the aforementioned manufacturing steps, in a direction intersecting with the lengthwise direction.

The manufacturing method for a laminated body according to the present embodiment is configured as described above.

According to the manufacturing method for a laminated body configured as above, it is possible to provide a manufacturing method for a laminated body that is able to suppress damage to the thin film layer having a gas barrier property and to suppress the occurrence of appearance defects.

### Modification Example

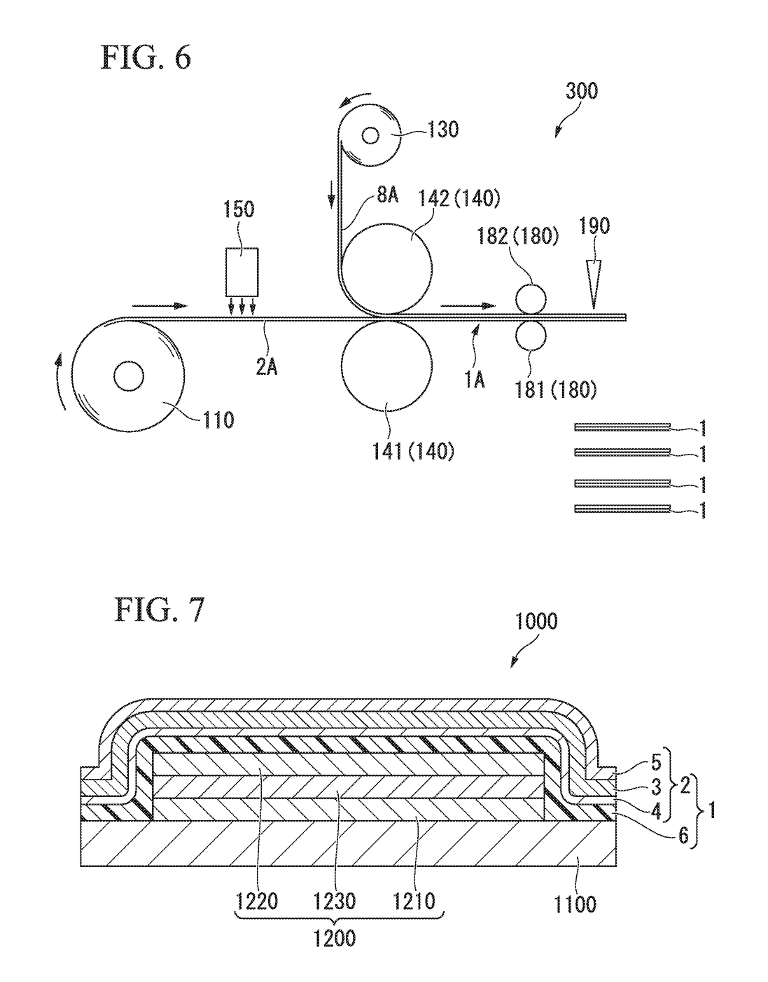

FIG. 6 is an explanatory diagram illustrating a modification example of the above-described embodiment which corresponds to FIG. 4 of the first embodiment. The manufacturing device 300 illustrated in FIG. 6 comprises a first unwinding roller 110, a second unwinding roller 130, a bonding roller 140, a surface treatment device 150, a conveyance roller 180 and a cutting device 190.

The conveyance roller 180 is provided on the conveyance path of the laminated film material 2A (laminated body material 1A), downstream from the bonding roller 140. The conveyance roller 180 has a pair of rollers, i.e. a roller 181 and a roller 182. The laminated body material 1A is pinched between the pair of rollers 181 and 182 and conveyed downstream.

The cutting device 190 is provided on the conveyance path of the laminated film material 2A (laminated body material 1A), downstream from the conveyance roller 180. The cutting device 190 cuts the laminated body material 1A that is conveyed thereto at predetermined lengths in a direction intersecting with the lengthwise direction of the laminated body material 1A, so as to consecutively manufacture laminated bodies 1.

With the manufacturing method for a laminated body using a manufacturing device 300 as described above, by implementing a step of cutting the laminated body material 1A using the cutting device 190 to manufacture the laminated bodies 1, it is possible to consecutively manufacture laminated bodies 1 without winding the laminated body material 1A onto the winding roller 120 shown in FIG. 4.

In other words, one aspect of the method for manufacturing a laminated body according to the present invention includes a step of manufacturing laminated bodies 1 by cutting the laminated body material 1A using the cutting device 190, without winding the laminated body material 1A onto the winding roller 120.

In the manufacturing device 200 according to the second embodiment illustrated in FIG. 5, the manufacturing device may have the above-mentioned conveyance roller 180 and the cutting device 190 positioned downstream from the curing device 170 instead of the winding roller 120. A manufacturing method for a laminated body using such a manufacturing device is also capable of consecutively manufacturing laminated bodies 1.

### [Organic EL Device]

FIG. 7 is a schematic diagram of an organic EL device using a laminated body manufactured by the manufacturing method for a laminated body according to the present embodiment.

The organic EL device 1000 illustrated in the drawing has a substrate board 1100, an organic EL element 1200 provided on the substrate board 1100, and a laminated body 1 provided on the substrate board 1100 and the organic EL element 1200. As the laminated body 1, one manufactured by the above-mentioned manufacturing method for a laminated body may be used.

When the organic EL element 1200 has a bottom-emission structure wherein light is extracted from the substrate board 1100 side, a substrate board 1100 having a light-transmitting property is used. Additionally, when the organic EL element 1200 has a top-emission structure wherein the light is extracted from the side opposite to the substrate board 1100, the substrate board 1100 may have a light-transmitting property, or may be opaque.

The material forming an opaque substrate board may, for example, be a ceramic such as alumina, or a resin. Additionally, a substrate board obtained by insulating the surface of a metal plate may be used. The material forming a substrate board having a light-transmitting property may be an inorganic substance such as glass or quartz, or may be a resin material such as an acrylic resin or a polycarbonate resin. Of these, when the material forming the substrate board is a resin material, the material should preferably be subjected to a gas barrier treatment as appropriate.

The substrate board 1100 may have flexibility, or may lack flexibility.

The organic EL element 1200 comprises an anode 1210, a cathode 1220, and an organic light-emitting layer 1230 sandwiched between the anode 1210 and the cathode 1220.

The anode 1210 is formed from a generally known material such as indium tin oxide, indium zinc oxide, tin oxide or the like.

The cathode 1220 is formed from a material having a lower work function (e.g., less than 5 eV) than the anode 1210. Examples of the material forming the cathode 1220 include calcium, magnesium, sodium, lithium metal, metal fluorides such as calcium fluoride or metal oxides such as lithium oxide, and organic metal complexes such as calcium acetylacetonate. When the organic EL element 1200 has a top-emission structure, the cathode 1220 can be provided with a light-emitting property by selecting the thickness or the material of the cathode 1220.

As the organic light-emitting layer 1230, a light-emitting material that is generally known as a material for forming organic EL elements may be used. The material forming the organic light-emitting layer 1230 may be a low molecular weight compound, or may be a high molecular weight compound.

The laminated body 1 is bonded to the substrate board 1100 and the organic EL element 1200, with the adhesive layer 6 facing towards the organic EL element 1200, so as to seal the organic EL element 1200 in the space enclosed by the laminated body 1 and the substrate board 1100. In the drawings, only a section view in one direction is shown, but the organic EL element 1200 is surrounded by the laminated body 1 and the substrate board 1100 in all directions.

In an organic EL device 1000 having such a structure, the organic EL element 1200 is sealed using the above-mentioned laminated body, so the thin film layer having a gas barrier property is not easily damaged, and the device is highly reliable. Additionally, the occurrence of appearance defects is suppressed in the laminated body 1 that is used, so the laminated body 1 has a good appearance. Furthermore, when the organic EL device 1000 is provided with a top-emission type organic EL element 1200, the emitted light is emitted to the outside through the laminated body 1, but since the formation of wrinkles in the adhesive layer 6 is suppressed in the laminated body 1, the emitted light is effectively emitted to the outside without being refracted or scattered.

While examples of preferred embodiments of the present invention have been explained by referring to the attached drawings, it is needless to say that the present invention is not to be construed as being limited to these examples. The shapes and combinations of the constituent elements indicated in the above-described examples are merely exemplary, and various modifications are possible in accordance with design requirements or the like within a range not departing from the gist of the present invention.

For example, in the above-mentioned embodiments, the step of forming the adhesive layer is performed while applying a tensile force to the laminated film material 2A or the adhesive film 8A in the lengthwise direction, but the direction of application of tensile force is not limited thereto. The step of forming the adhesive layer may be performed by applying a tensile force so as the spread the laminated film material 2A or the adhesive film 8A in the widthwise direction in addition to the lengthwise direction, in other words, while applying tensile forces to the film along two axes.

### Examples

While the present invention will be explained herebelow by reference to examples, the present invention is not to be construed as being limited to these examples.

### [Laminated Film]

In the following examples and comparative examples, laminated films manufactured by the following methods were used.

A laminated film was manufactured using the above-described manufacturing device illustrated in FIG. 3.

A biaxially stretched polyethylene naphthalate film (Teijin DuPont Films, PQDA5, thickness 100 μm, width 700 mm) was used as the substrate, and loaded onto a feed-out roller in a vacuum chamber. After setting the inside of the vacuum chamber to 1×10⁻³ Pa or less, a thin film layer was formed on the substrate while conveying the substrate at a constant speed of 0.5 m/min. The biaxially stretched polyethylene naphthalate film used for the substrate has an asymmetric structure that is subjected to an easy-adhesion treatment (primer treatment) on one surface, and has a thin film layer formed on the surface that is not subjected to the easy adhesion treatment. In the plasma CVD device used for forming the thin film layer, a plasma is generated between a pair of electrodes, and the substrate is conveyed while coming into close contact with the electrode surfaces, so as to form a thin film layer on the substrate. Additionally, the pair of electrodes have magnets disposed inside the electrodes so that the magnetic flux density becomes high at the electrodes and the substrate surface, and the plasma is captured at a high density at the electrodes and on the substrate during plasma generation.

During film formation of the thin film layer, 100 sccm (standard cubic centimeters per minute, 0° C., 1 atm standard) of hexamethyldisiloxane gas and 900 sccm of oxygen gas were introduced into the space between the electrodes forming the film formation zone, and an AC power of 1.6 kW and a frequency of 70 kHz was supplied between the electrode rollers so as to cause a discharge and generate plasma. Next, after adjusting the exhaust amount so as to set the pressure in the vicinity of the exhaust port in the vacuum chamber to 1 Pa, a thin film layer was formed on the conveyed substrate by means of plasma CVD. This step was repeated four times.

The film thickness of the thin film layer of the laminated film was determined by measuring the step difference between a non-film-formed portion and a film-formed portion of the laminated film using a Kosaka Laboratory Surfcorder ET200. The film thickness of the thin film layer of the resulting laminated film was 700 nm.

The total light transmittance of the laminated film was measured by means of a Suga Test Instruments direct-reading haze computer (Model HGM-2DP). After taking background measurements in the absence of a sample, a laminated film was set in the sample holder and measurements were made. The total light transmittance of the resulting laminated film was 87%.

The water vapor permeability of the laminated film was determined by measurements using a calcium corrosion method (the method described in JP 2005-283561 A) at a temperature of 40° C. and a humidity of 90% RH. The water vapor permeability of the resulting laminated film was 2×10⁻⁵ g/m²/day.

For the resulting laminated film, the atomic ratios were greater in the order of oxygen, silicon and carbon in an area of at least 90% in the film thickness direction of the thin film layer, there were 10 or more extreme values in the carbon distribution curve in the film thickness direction, and the absolute value of the difference between the maximum value and the minimum value of the atomic ratio of carbon in the carbon distribution curve was 15 at % or more.

Additionally, the resulting laminated film was subjected to an XPS depth profile measurement under the below-mentioned conditions, and the resulting distribution curves for silicon atoms, nitrogen atoms, oxygen atoms and carbon atoms were determined.

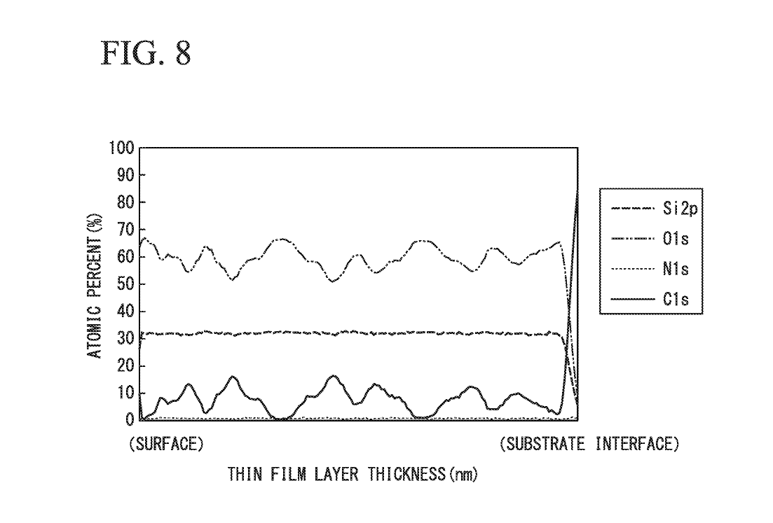

FIG. 8 is a graph showing the silicon distribution curve, the oxygen distribution curve, the nitrogen distribution curve and the carbon distribution curve of the thin film layer in the laminated film 1 obtained in Manufacturing Example 1.

### <XPS Depth Profile Measurement>

Etching ion species: argon (Ar⁺)
Etching rate (SiO₂ thermal oxide film-converted value): 0.05 nm/sec
Etching interval (SiO₂-converted value): 10 nm
X-ray photoelectron spectroscopy device: Thermo Fisher Scientific, Model “VG Theta Probe”
Irradiated X-rays: single crystal spectral A1Kα
X-ray spot and size thereof: 800×400 m ellipse

### Example 1

The above-mentioned laminated film and a transparent double-sided adhesive tape (Lintec TL-430S-06, 30 μm thick) were bonded together using rollers while respectively applying the below-mentioned tensile forces to manufacture the laminated body of Example 1. At that time, the transparent double-sided adhesive tape was bonded to the side of the laminated film having the thin film layer.

The transparent double-sided adhesive tape corresponds to the “adhesive film 8A” in the above-mentioned embodiments, and the adhesive layers of the transparent double-sided adhesive tape correspond to the “adhesive layer 6A” and the “adhesive layer 6” in the above-mentioned embodiments.

### (Bonding Conditions)

Tensile force per unit cross-sectional area of laminated film: 39 N/mm²
Tensile force per unit cross-sectional area of transparent adhesive double-sided tape: 0.1 N/mm²

### Example 2

A laminated body of Example 2 was manufactured in the same manner as Example 1 aside from the fact that the bonding conditions were changed to the below-mentioned conditions.

### (Bonding Conditions)

Tensile force per unit cross-sectional area of laminated film: 0.5 N/mm²
Tensile force per unit cross-sectional area of transparent adhesive double-sided tape: 0.1 N/mm²

### Comparative Example 1

A laminated body of Comparative Example 1 was manufactured in the same manner as Example 1 aside from the fact that the bonding conditions were changed to the below-mentioned conditions.

### (Bonding Conditions)

Tensile force per unit cross-sectional area of laminated film: 62.5 N/mm²
Tensile force per unit cross-sectional area of transparent adhesive double-sided tape: 0.1 N/mm²

### Comparative Example 2

The laminated body of Comparative Example 2 was manufactured in the same manner as Example 1 aside from the fact that the bonding conditions were changed to the below-mentioned conditions.

### (Bonding Conditions)

Tensile force per unit cross-sectional area of laminated film: none
Tensile force per unit cross-sectional area of transparent adhesive double-sided tape: 0.1 N/mm²

The resulting laminated bodies were evaluated using the below-described methods.

### (Evaluation 1: Observation of Appearance)

The appearances of the resulting laminated bodies were evaluated by eye.

### (Evaluation 2: Impact Resistance Test)

Test pieces were prepared by cutting out pieces measuring 2 cm square from the resulting laminated bodies. The test pieces were mounted on a test stand with the laminated film facing down and the transparent double-sided adhesive tape facing up, after which an impact was applied by dropping an iron ball (diameter 1 inch (2.54 cm), weight 68 g) from a position 10 nm above the laminated body.

After dropping the ball, the laminated body was observed using a microscope (Hirox DIGITAL MICROSCOPE KH7700) at 210 times magnification, and the number of cracks in the thin film layer present within a viewing range of 1.8 mm×1.4 mm was measured.

The evaluation results are shown in the below-indicated Table 1. In Table 1, pieces having neither wrinkles nor cracks were rated “A” as being satisfactory products, and those having either wrinkles or cracks were rated “B” as being defective. Additionally, in Table 1, the transparent double-sided adhesive tape that was used was simply indicated as being “adhesive tape”.

TABLE 1

| | Tensile force | Tensile force | | | |
|---|---|---|---|---|---|
| | on laminated | on adhesive | | Number | |
| | film | tape | | of | |
| | (N/mm²) | (N/mm²) | Wrinkles | cracks | Rating |
| Example 1 | 39 | 0.1 | absent | 0 | A |
| Example 2 | 1 | 0.1 | absent | 0 | A |
| Comparative | 62.5 | 0.1 | absent | 14 | B |
| Example 1 | | | | | |
| Comparative | none | 0.1 | present | 0 | B |
| Example 2 | | | | | |

As a result of the evaluations, the laminated bodies of Examples 1 and 2 did not have wrinkles after bonding, and the thin film layers did not have any cracks within the observed field of view after the impact resistance test.

On the other hand, in the laminated body of Comparative Example 1, there were no wrinkles after bonding, but the thin film layer had 14 cracks in the observed field of view after the impact resistance test.

Additionally, in the laminated body of Comparative Example 2, the thin film layer did not have any cracks in the observed field of view after the impact resistance test, but wrinkles were formed in the transparent double-sided tape.

The above-mentioned results show that the present invention is useful.

### REFERENCE SIGNS LIST

1 Laminated body
1A Laminated body material
2 Laminated film
2A Laminated film material
3 Substrate
3A Substrate material
4 Thin film layer
4a First layer
4b Second layer
5 Curl-suppressing layer
6, 6A Adhesive layer
7A Separator film
8A Adhesive film
10 Film formation device
11 Unwinding roller
12 Winding roller
13 Conveyance roller
17, 18 Film formation roller
19 Gas supply pipe
20 Plasma-generating power source
21 Electrode
23 Magnetic field generation device
23a, 24a Central magnet
23b, 24b External magnet
24 Magnetic field generation device
60 Coating film
100, 200, 300 Manufacturing device
110 First unwinding roller
120 Winding roller
130 Second unwinding roller
140 Bonding roller
141, 142 Roller
150 Surface treatment device
160 Coating device
170 Curing device
180 Conveyance roller
181, 182 Roller
190 Cutting device
1000 Organic EL device
1100 Substrate board
1200 Organic EL element
1210 Anode
1220 Cathode
1230 Organic light-emitting layer
SP Space

1. A manufacturing method for a laminated body having a laminated film and an adhesive layer,
the manufacturing method comprising a step of forming the adhesive layer on one surface of the laminated film, wherein
the laminated film is a laminated film on which at least a substrate, and a thin film layer containing at least silicon are laminated, and
the step of forming the adhesive layer includes forming the adhesive layer on a surface of a laminated film material in which the thin film layer is laminated while conveying the laminated film material in which the laminated film is continuous in strip shape in a lengthwise direction, and while applying a tensile force of at least 0.5 N/mm² and less than 50 N/mm² per unit of cross-sectional area, in the lengthwise direction, to the laminated film material.

2. The manufacturing method for a laminated body according to claim 1, wherein the step of forming the adhesive layer further includes bonding an adhesive layer material, onto the laminated film material, while conveying the adhesive layer material in which the adhesive layer is continuous in strip shape in the lengthwise direction, and while applying a tensile force of at least 0.01 N/mm² and less than 5 N/mm² per unit of cross-sectional area, in the lengthwise direction, to the adhesive layer material.

3. The manufacturing method for a laminated body according to claim 1, further comprising a step of forming the thin film layer on at least one surface of the substrate;
wherein the step of forming the thin film layer includes continuously forming the thin film layer on at least one surface of a substrate material, while continuously conveying the substrate material in which the substrate is continuous in strip shape.

4. The manufacturing method for a laminated body according to claim 3, wherein the step of forming the thin film includes:
applying an AC voltage between a first film formation roller over which the substrate material is wound, and a second film formation roller over which the substrate material is wound and which is provided so as to face the first film formation roller, thereby generating a discharge plasma of a film-forming gas, which is a material for forming the thin film layer, in a space between the first film formation roller and the second film formation roller; and
forming the thin film layer on the surface of the substrate material by plasma CVD using the generated discharge plasma.

5. The manufacturing method for a laminated body according to claim 4, wherein
the AC voltage is applied and a magnetic field is formed so that, by forming an AC electric field between the first film formation roller and the second film formation roller, and forming an endless tunnel-shaped magnetic field extending in the space across which the first film formation roller and the second film formation roller face each other, the discharge plasma includes a first discharge plasma that is formed along the tunnel-shaped magnetic field, and a second discharge plasma that is formed in a periphery of the tunnel-shaped magnetic field; and
the step of forming the thin film layer includes conveying the substrate material so as to coincide with the first discharge plasma and the second discharge plasma.

6. The manufacturing method for a laminated body according to claim 4, wherein:
the thin film layer contains at least silicon, oxygen and carbon; and
the step of forming the thin film layer includes controlling a mixing ratio between an organic silicon compound and oxygen contained in the film-forming gas so that, in the formed thin film layer, a silicon distribution curve, an oxygen distribution curve and a carbon distribution curve, respectively indicating a relationship between the distance from a surface of the thin film layer in a film thickness direction of the thin film layer, and the atomic ratio of silicon, which is the ratio of the number of silicon atoms, the atomic ratio of oxygen, which is the ratio of the number of oxygen atoms, and the atomic ratio of carbon, which is the ratio of the number of carbon atoms, with respect to the total number of silicon atoms, oxygen atoms and carbon atoms contained in the thin film layer at a point located at the distance, satisfy the following conditions (i) to (iii):
(i) the atomic ratio of silicon, the atomic ratio of oxygen and the atomic ratio of carbon satisfy the conditions represented by the following expression (1) in a region that is at least 90% of the entire film thickness of the thin film layer:
(Atomic ratio of oxygen)>(atomic ratio of silicon)>(atomic ratio of carbon) (1);
(ii) the carbon distribution curve has at least one extreme value; and
(iii) the absolute value of the difference between the maximum value and the minimum value of the atomic ratio of carbon in the carbon distribution curve is at least 0.05 at %.

7. The manufacturing method for a laminated body according to claim 6, wherein the absolute value of the difference between the maximum value and the minimum value of the atomic ratio of silicon in the silicon distribution curve of the thin film layer is less than 5 at %.

8. The manufacturing method for a laminated body according to claim 1, wherein the thin film layer comprises SiOₓC_{y}, where 0<x<2 and 0<y<2.
